(19) United States
(12) Patent Application Publication
(10) Pub. No.: US 2026/0223679 A1
(43) Pub. Date: Jul. 30, 2026

(54) ENHANCING HEAT TRANSFER IN THERMOSYPHONS

(71) Applicant: KV INNOVATIONS, LLC, Albuquerque, NM (US)

(72) Inventors: Kambiz Vafai, Mission Viejo, CA (US); Raha Kalantarpour, Mission Viejo, CA (US)

(21) Appl. No.: 19/452,287

(22) Filed: Jan. 18, 2026

Related U.S. Application Data
(60) Provisional application No. 63/747,056, filed on Jan. 19, 2025.

(51) Int. Cl. H10W 40/73

(52) U.S. Cl. CPC H10W 40/73

(57) ABSTRACT

An apparatus, method, and system for cooling electronic components, can include a thermosyphons thermally coupled to one or more electronic components, wherein the thermosyphon is configured to transfer heat away from the electronic components by phase change of a working fluid circulating within the thermosyphon. In an embodiment, the thermosyphon can be implemented as a flat-shaped thermosyphon having an evaporator region, a condenser region, and a fluid return path formed within a flattened enclosure. The electronic component can be, for example, a data center electronic device, an integrated circuit, a processor, a power electronic module, or a printed circuit board assembly. The working fluid can be provided as a self-rewetting fluid that exhibits a surface tension that increases with increasing temperature over at least a portion of an operating temperature range, thereby promoting liquid migration toward heated regions of the thermosyphon.

### CROSS REFERENCE TO PATENT APPLICATION

This patent application claims priority under 35 U.S.C. § 119 to U.S. Provisional Patent Application Ser. No. 63/747,056 filed on Jan. 19, 2025, which is incorporated herein by reference herein in its entirety.

### TECHNICAL FIELD

Embodiments relate to generally relates to methods and systems for thermal management of electronic devices. More particularly, embodiments relate to apparatuses, systems, and methods for cooling heat-generating electronic components, including integrated circuits and power electronic devices. Embodiments further relate to passive and two-phase heat transfer devices, and, more specifically, to thermosyphon-based cooling structures configured to transfer heat away from electronic components through phase-change-driven fluid circulation.

### BACKGROUND

The increasing demand for miniaturized electronic devices with higher power densities has led to a need for more efficient cooling systems. As the size of these devices decreases, the rate of thermal losses is increasing at a rapid pace. Moreover, extended exposure of electronic devices to high temperatures can cause decreased performance and lead to eventual failure. Significant fluctuations in temperature can create thermal and mechanical stress. If these stresses are not managed properly, they may undermine the reliability and safety of the device's components. As the electronic devices become smaller and more powerful, effectively dissipating the heat they generate becomes increasingly challenging. The development of power electronic devices requires the consideration of an acute and effective cooling system to ensure optimal performance and prevent damage from over-heating. Therefore, the design and optimization of cooling systems have become crucial.

Researchers have been working extensively in recent decades to improve the thermal management of electronic cooling systems. Most thermal management technologies employ heat sinks connected to the heat source. The heat sink functions by conducting heat away from the thermal source and then releasing it into the surrounding environment. The effectiveness of the thermal management system, and consequently the performance of electronic devices, is heavily influenced by the heat sink's geometry and the thermo-physical characteristics of its material.

Conventional single-phase cooling methods have reached their limits and are no longer sufficient to meet the growing demands for cooling in electronic devices. Meanwhile, the phase change process takes advantage of the latent heat during evaporation, to effectively dissipate a significant amount of heat while maintaining a relatively low device surface temperature. Heat pipes, for example, employing the phase change process are widely used in electronic devices as heat sinks and heat spreaders. One of the most desirable types of heat pipes is thermosyphons, which allow the system to eliminate the wick by utilizing the force of gravity. Wickless heat pipes (thermosyphons) can operate under a wider range of operating conditions compared to wicked heat pipes. Also, their compactness, simplicity, and lower manufacturing expense make them a great choice for cooling systems.

Although thermosyphons possess useful qualities, the dry out phenomenon is a significant limitation that can seriously decrease their efficiency. There are some proposed solutions to overcome this shortcoming like using self-rewetting fluid as the working fluids and surface coating on the evaporator and condenser.

In the last few decades, the thermal performance of thermosyphons has been extensively studied and documented. Lu and Vafai investigated the thermal performance of 3D ICs using rectangular and disk-shaped heat pipes as heat sinks and heat spreaders. The study found that replacing a copper heat spreader with a flat-shaped heat pipe can further optimize thermal performance, with a reduction in hotspot temperature of up to 17 K. Zhang et al. experimentally investigated the characteristics of phase change heat transfer and the performance of the two-phase thermosyphon with different working fluids and grooved evaporation surface. They found that water, as a working fluid, outperformed ethanol in terms of heat dissipation, and that the grooved evaporator surface improved the overall heat transfer rate. In a later study, they presented an axisymmetric two-dimensional heat and mass transfer model for a disk-shaped flat two-phase thermosyphon. For simplification, they assumed that the liquid circulation is well established inside the thermosyphon and there would be no observation for the occurrence of drying out. Sundaram and Bhaskaran studied the performance of a thermosyphon integrated heat sink for CPU cooling by evaluating the equivalent thermal resistance of the thermosyphon, and it is found to be superior to conventional cooling methods.

Schepper et al. have developed a model for simulating the flow boiling process and proposed some equations to calculate the mass and energy transfer phenomena that occur during this process. Aliza-dehdakhel et al. used these proposed equations to model a two-phase flow along with evaporation and condensation in a thermosyphon using the Volume of Fluid (VOF) technique. By comparing the numerical results with experimental tests, they concluded that CFD is a useful tool for modeling and explaining the complex flow and heat transfer in a thermosyphon. According to Lenhard et al., the use of numerical modeling in phase-change heat transfer is an efficient and cost-effective method. However, they have shown that 2D numerical simulation is not suitable for modeling thermosyphons.

Therefore, they strongly recommend utilizing 3D models to study the evaporation and condensation processes in such devices. Hosseinzadeh et al. suggested the use of an axisymmetric model for simulating thermosyphons. Since the stresses and constraints acting on the thermosyphon are purely radial and axial, an axisymmetric model is a suitable choice for simulation. The axisymmetric modeling approach can provide a reasonable solution compared to 2D simulations and significantly reduces the computational cost of 3D modeling. They demonstrated that the axisymmetric model is in good agreement with experimental data, indicating its effectiveness in simulating thermosyphons.

The choice of the working fluid plays a significant role in the performance of thermosyphons, as it directly affects the heat transfer characteristics and system efficiency. Different working fluids have varying thermophysical properties, such as density, specific heat capacity, viscosity, and surface tension, which directly affect the system's thermal behavior. Some fluids may have a better heat transfer coefficient, while others may have a higher boiling point or a lower viscosity, which can affect the startup and circulation in the thermosyphon. Hence, selecting an appropriate working fluid is essential to achieve optimal thermal performance and meet the desired application requirements. The impact of the working fluid on the thermosyphon's performance has been experimentally and numerically investigated by many studies to determine the most suitable fluid for a particular application. Some of the suggested working fluids that have been studied in thermosyphons include refrigerants, self-rewetting fluids, Fluorinerts, and nanofluids. Refrigerants such as R134a and R11 have been used due to their high heat transfer coefficients.

Self-rewetting fluids like 1-butanol aqueous solutions have also been investigated due to their ability to enhance the heat transfer co-efficient by spreading on the heated surface. Nanofluids, which are suspensions of nanoparticles in a base fluid, have also been studied as they can enhance working fluid transport properties due to the high surface area of the nanoparticles. In an experimental study, Asirvatham et al. showed the maximum reduction of 70.3% for thermal resistance in a thermosyphon by using 0.09% graphene acetone nanofluids. Furthermore, Jiang et al. investigated the thermal resistance of inclined thermosyphons with SiC particles added to the working fluid. They concluded that adding SiC particles reduces the thermal resistance of the thermosyphon for different inclination angles.

Savino et al. proposed using self-rewetting fluids (SRWF) in heat pipes to improve thermal performance. Unlike ordinary fluids, self-rewetting fluids exhibit a positive surface tension gradient with temperature, meaning that the surface tension of the fluid increases with temperature. This unique property enables the fluid to spread on a heated surface, enhancing the heat transfer coefficient and improving the thermal performance of the system. In heat pipes, SRWFs demonstrate an inverse Marangoni flow and move from cold to hot regions. This specific and unusual behavior is highly favorable for avoiding dry-outs in thermosyphons.

Later, Savino et al. compared the behavior of self-rewetting fluids with ordinary working fluids in the heat pipes. It was found that the heat pipe filled with water experiences complete drying out at higher power inputs (40 W). However, in the case of the self-rewetting fluid at the same input power, a strong flow of liquid from the cold to the hot region was observed due to the inverse Marangoni effect. This flow beneficially rewets the evaporator and prevents drying out, making it a promising working fluid for various applications. In another research, Su et al. investigated the self-rewetting nanofluids in oscillating heat pipes by mixing graphene oxide dispersion solution in n-butanol aqueous solution. Results showed that self-rewetting nano-fluids enhance heat transfer due to combined high thermal conductivity and inversed Marangoni effect. Optimal nanofluid concentration im-proves thermal performance, reaching a 16% enhancement over self-rewetting fluid and 12% over nanofluid.

Later, Wang et al. numerically examined the impact of varying nanoparticle concentrations in thermosyphons, comparing the results to those obtained with pure water. Their findings showed that the incorporation of nanofluids led to a notable improvement in the thermal performance of thermosyphons, achieved by reducing the evaporator temperature. The study's findings closely match with experimental data, confirming the accuracy of the numerical model. In another study carried out by Liang et al., the heat transfer performance of different fluids in a pulsating heat pipe was analyzed. Notably, the n-butanol self-rewetting fluid solution exhibited the most considerable improvement with higher thermal input. Additionally, n-butanol self-rewetting nanofluids (SRNFs) demonstrated a remarkable enhancement in thermal efficiency, particularly within a lower heating power range, with the peak effect observed at 35 W. The researchers concluded that self-rewetting nano-fluids offer combined benefits of both self-rewetting fluids and nanofluids.

Hosseinzade et al. utilized a combination of a super-hydrophobic coating on the condenser and a 1-butanol aqueous solution as a self-rewetting working fluid. The results showed that the thermosyphons with a super-hydrophobic condenser have a higher convective heat transfer coefficient compared to the thermosyphons with a non-modified condenser, due to the dropwise condensation. Also, they observed that boiling occurred faster in the thermosyphons with 1-butanol aqueous solution working fluid compared to the water-charged thermosyphons.

### BRIEF SUMMARY

The following summary is provided to facilitate an understanding of some of the innovative features unique to the disclosed embodiments and is not intended to be a full description. A full appreciation of the various aspects of the embodiments disclosed herein can be gained by taking the entire specification, claims, drawings, and abstract as a whole.

It is, therefore, one aspect of the embodiments to provide for methods and systems for thermal management of electronic devices.

It is another aspect of the embodiments to provide for apparatuses, systems, and methods for cooling heat-generating electronic components, including integrated circuits and power electronic devices.

It is another aspect of the embodiments to provide passive and two-phase heat transfer devices, and, more specifically, to thermosyphon-based cooling structures configured to transfer heat away from electronic components through phase-change-driven fluid circulation.

It is another aspect of the embodiments to provide for methods and systems for enhancing heat transfer in thermosyphons.

The aforementioned aspects and other objectives and advantages can now be achieved as described herein. An apparatus for cooling electronic components, can include at least one thermosyphon thermally coupled to at least one electronic component, wherein the at least one thermosyphon is configured to transfer heat away from the electronic component by phase change of a working fluid circulating within the at least one thermosyphon.

In an embodiment, the at least one thermosyphon can be implemented as a flat-shaped thermosyphon having an evaporator region, a condenser region, and a fluid return path formed within a flattened enclosure.

In an embodiment, the electronic component can be, for example, a data center electronic device, an integrated circuit, a processor, a power electronic module, or a printed circuit board assembly.

In an embodiment, the working fluid can be a self-rewetting fluid.

In an embodiment, the self-rewetting fluid exhibits a surface tension that increases with increasing temperature over at least a portion of an operating temperature range, thereby promoting liquid migration toward heated regions of the thermosyphon.

In an embodiment, the self-rewetting fluid can be an aqueous solution containing an alcohol.

In an embodiment, the working fluid further can be a self-rewetting nanofluid including nanoparticles dispersed within the self-rewetting fluid.

In an embodiment, the nanoparticles can comprise metal oxide nanoparticles.

In an embodiment, the self-rewetting fluid can be configured to reduce dry-out at an evaporator surface by attracting liquid toward regions of higher temperature.

In an embodiment, the at least one thermosyphon has a working fluid filling ratio selected to reduce a maximum temperature at an evaporator plate during steady-state operation.

In an embodiment, the flat-shaped thermosyphon can be configured to be mounted directly to a heat-generating surface of the electronic component.

An embodiment can further include a plurality of thermosyphons arranged in parallel to cool multiple electronic components or multiple regions of a single electronic component, the plurality of thermosyphon including the at least one thermosyphon.

In an embodiment, the self-rewetting nanofluid can be configured to maintain stable thermal performance under high heat flux conditions relative to a thermosyphon using water as a working fluid.

In an embodiment, an evaporator surface of the thermosyphon can comprise a metallic heat transfer surface.

In an embodiment, a method for cooling an electronic component, can further involve: thermally coupling a thermosyphon to a heat-generating surface of the electronic component; circulating a working fluid within the thermosyphon by evaporation at an evaporator region and condensation at a condenser region; and using a self-rewetting working fluid within the thermosyphon such that, as temperature increases at the evaporator region, surface tension of the working fluid increases and draws liquid toward hotter regions, thereby reducing dry-out and enhancing heat transfer during operation of the electronic component.

In an embodiment, a system for cooling electronic components, can include an electronic component; and at least one thermosyphon thermally coupled to the electronic component, wherein the thermosyphon contains a self-rewetting working fluid configured to circulate within the thermosyphon by phase change and to preferentially wet higher-temperature regions of an evaporator surface during operation.

In an embodiment, the thermosyphon can be a flat-shaped thermosyphon configured for direct attachment to the electronic component, and the self-rewetting working fluid can be a self-rewetting nanofluid including nanoparticles dispersed within an aqueous alcohol solution, the nanoparticles increasing thermal conductivity of the working fluid during boiling.

### BRIEF DESCRIPTION OF THE DRAWINGS

The accompanying figures, in which like reference numerals refer to identical or functionally-similar elements throughout the separate views and which are incorporated in and form a part of the specification, further illustrate the present invention and, together with the detailed description of the invention, serve to explain the principles of the present invention.

FIG. 1 illustrates a schematic diagram of a thermosyphon, in accordance with an embodiment;

FIG. 2 illustrates a graph depicting data indicative of surface tensions of different working fluids as functions of temperature in accordance with an embodiment;

FIG. 3 illustrates a graph depicting data indicative of the validation of temperature distribution in a disk shaped thermosyphon, in accordance with an embodiment;

FIG. 4 illustrates a graph depicting validation and comparison of temperature distribution in thermosyphon with experimental data with different working fluids, in accordance with an embodiment;

FIG. 5 illustrates a graph of data stemming from a grid independent study for the flat-shaped thermosyphon, in accordance with an embodiment;

FIG. 6 illustrates a schematic diagram of grid distribution in the domain and near walls, in accordance with an embodiment;

FIG. 7 illustrates the volume fraction of liquid in the boiling process with time steps, (a) water, (b) SRWF, with 50% filling ratio and 120 W heat input, in accordance with an embodiment;

FIG. 8 illustrates a graph of maximum temperature on the heater for different working fluids and heat fluxes, and a graph of average temperature of the heater for different working fluids and heat fluxes, in accordance with an embodiment;

FIG. 9 illustrates a graph of data indicative of the average bottom plate temperature over time for different filling ratios and heat power levels using an aqueous solution of butanol 2% as the working fluid, in accordance with an embodiment;

FIG. 10 illustrates a graph of data indicative temperature distribution on the bottom plate for different working fluids with 160 W heat input and 50% filling ratio, in accordance with an embodiment;

FIG. 11 illustrates an example of a system for cooling electronic components, in accordance with an embodiment;

FIG. 12 illustrates a schematic diagram of an apparatus for cooling electronic components, in accordance with an embodiment; and

FIG. 13 illustrates a schematic diagram of a system for cooling data center components, in accordance with an embodiment.

### DETAILED DESCRIPTION

The particular values and configurations discussed in these non-limiting examples can be varied and are cited merely to illustrate one or more embodiments and are not intended to limit the scope thereof.

Subject matter will now be described more fully hereinafter with reference to the accompanying drawings, which form a part hereof, and which show, by way of illustration, specific example embodiments. Subject matter may, however, be embodied in a variety of different forms and, therefore, covered or claimed subject matter is intended to be construed as not being limited to any example embodiments set forth herein; example embodiments are provided merely to be illustrative. Likewise, a reasonably broad scope for claimed or covered subject matter is intended. Among other things, for example, subject matter may be embodied as methods, devices, components, or systems. Accordingly, embodiments may, for example, take the form of hardware, software, firmware, or any combination thereof (other than software per se). The following detailed description is, therefore, not intended to be interpreted in a limiting sense.

Throughout the specification and claims, terms may have nuanced meanings suggested or implied in context beyond an explicitly stated meaning. Likewise, phrases such as “in one embodiment” or “in an example embodiment” and variations thereof as utilized herein do not necessarily refer to the same embodiment and the phrase “in another embodiment” or “in another example embodiment” and variations thereof as utilized herein may or may not necessarily refer to a different embodiment. It is intended, for example, that claimed subject matter include combinations of example embodiments in whole or in part. In addition, identical reference numerals utilized herein with respect to the drawings can refer to identical or similar parts or components.

In general, terminology may be understood, at least in part, from usage in context. For example, terms such as “and,” “or,” or “and/or” as used herein may include a variety of meanings that may depend, at least in part, upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein, depending at least in part upon context, may be used to describe any feature, structure, or characteristic in a singular sense or may be used to describe combinations of features, structures, or characteristics in a plural sense. Similarly, terms such as “a,” “an,” or “the”, again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

As previously stated, the thermal performance of thermosyphons is significantly affected by surface wettability and working fluid's properties. In a previous study we conducted an analysis of the thermosyphon's performance using various working fluids, such as water and SRWFs, along with different surface wettability modifications, including a super hydrophilic evaporator and a super hydrophobic condenser. This prior research provided valuable insights into the fac-tors affecting the thermosyphon's thermal efficiency and heat transfer characteristics. In the present study, we aimed to refine our simulations further. Recognizing the limitations of 2D models in adequately capturing the intricate phase change processes within the thermosyphon, we made a transition to an axisymmetric model.

This shift was grounded in the clear understanding that the predominant stress and constraint components acting on the thermosyphon are radial and axial, with negligible tangential components. This transition rooted in the specific geometry of the disk-shaped thermosyphon, which possesses a 3D structure due to its body-of-revolution nature. While 3D modeling would be computationally expensive, the axisymmetric model offered us to obtain 3D-like results while maintaining computational cost lower. Notably, prior studies, including the work of Lenhard et al., have emphasized the inadequacy of 2D models for effectively capturing the evaporation and condensation processes in thermosyphons. This shift allowed for a more comprehensive understanding of the phase change and heat transfer processes within the flat-shaped thermosyphon, enhancing the precision and reliability of our numerical simulations.

Additionally, we introduce a transient approach, capturing the dynamic evaporation and condensation processes in the flat-shaped thermosyphon. By doing so, we have unlocked a more comprehensive understanding of the intricate phase change and heat transfer processes within the flat-shaped thermosyphon. What sets this study apart is our exploration of the impact of self-rewetting nanofluid on the thermosyphon's performance. Our primary objective is threefold: to mitigate dry-out occurrences, augment heat input capacity, and achieve a more uniform temperature distribution. This novel focus on self-rewetting nanofluid introduces a pioneering element to the investigation, addressing critical aspects of thermosyphon behavior that have not been extensively explored in the existing literature.

The innovations of the embodiments lie not only in the refined simulation methodology, transitioning from 2D to axisymmetric modeling, but also in the pioneering exploration of self-rewetting nanofluid's influence on thermosyphon performance. These advancements aim to contribute significantly to the current understanding of thermosyphon behavior and offer insights that pave the way for improved thermal management systems.

There are two principal approaches to simulate multiphase flows: Euler-Lagrange and Euler-Euler approach. The fluid phase is treated like a continuum in Euler-Lagrange approach, while in Euler-Euler approach each phase is considered as a dispersed phase. There is a limitation of 10% for the dispersed phase in the Euler-Lagrange approach, which will be passed in the thermosyphon phase change process. Therefore, Euler-Euler will be employed in this simulation with two functions of volume fractions accounting for liquid and vapor.

Because of the moving interfaces and sudden change of physical properties at the interfaces, simulating multiphase flows by Finite Volume Method (FVM) is computationally expensive. However, in Volume of Fluid (VOF) technique the interface tracking is achieved by solving a single set of Navier-Stocks equations throughout the domain. Therefore, the VOF technique has been widely used by researchers to simulate the interaction between the vapor and liquid in the thermosyphons due to its simplicity. In VOF technique, volume fraction would be defined for each phase to determine the fraction of the volume of the given cell that is occupied by that phase. Here, in this study, al and av represent the volume fraction of liquid and vapor, respectively. Each computational cell throughout the domain may contain only liquid, only vapor, or a combination of them. The relation between the volume fraction of these two existing phases is as below:

$${α}_{l} + {α}_{v} = 1 \qquad ( 1 )$$

Based on the mass conservation law the continuity equation can be presented as:

$$∇ \cdot ( ρ \vec{u} ) = \frac{\partial ρ}{\partial t} \qquad ( 2 )$$

Where ρ_represents the density, u represents the velocity, and t rep-resents time. The continuity equation will be solved only for the secondary phase, which is liquid here. The volume fraction of the primary phase (vapor) can be obtained using Eq. (1). The continuity equation for the secondary phase is as follows:

$$∇ \cdot ( {α}_{l} {p}_{l} \vec{u} ) = - \frac{\partial }{\partial t} ( {α}_{l} {ρ}_{l} ) + {S}_{m} \qquad ( 3 )$$

Where Sm is the mass source term accounting for mass transfer in the phase change process. The density of the mixture can be obtained based on the density and volume fractions of each phase from the following equation:

$$ρ = {α}_{l} {ρ}_{l} + ( 1 - {α}_{l} ) {ρ}_{v} \qquad ( 4 )$$

The momentum equation in VOF technique is as given below:

$$\frac{\partial }{\partial t} ( ρ \vec{u} ) + ∇ . ( ρ {\vec{u} ( \vec{u} )}^{T} ) = pg - ∇ p + ∇ . [ μ ( ∇ \vec{u} ) + {( ∇ \vec{u} )}^{T} - \frac{2}{3} μ ( ∇ \vec{u} ) I ] + {F}_{CSF} \qquad ( 5 )$$

Where g is the gravity, p is the pressure, and μ_is the viscosity. The viscosity of the mixture can be evaluated based on the volume fraction of the phases:

$$μ = {α}_{l} {μ}_{l} + {α}_{v} {μ}_{v} \qquad ( 6 )$$

FCSF in the momentum equation is the source term to calculate the surface tension between the two phases, and can be obtained from following equation:

$${F}_{CSF} = 2 {σ}_{lv} \frac{{α}_{l} {ρ}_{l} {C}_{v} ∇ {α}_{v} + {α}_{v} {ρ}_{v} {C}_{l} ∇ {α}_{l}}{{ρ}_{l} + {ρ}_{v}} \qquad ( 7 )$$

Where σlv represents the surface tension coefficient and C stands for surface curvature.

The energy equation responsible to model the phase change process is given as follow:

$$\frac{\partial }{\partial t} ( ρe ) + ∇ . ( pe \vec{u} ) = ∇ . ( k . ∇ T ) + ∇ . ( p \vec{u} ) + {S}_{E} \qquad ( 8 )$$

SE is the source term to obtain the heat transfer due to the phase change in the energy equation. k represents thermal conductivity and can be evaluated by [21]:

$$k = {α}_{l} {k}_{l} + {α}_{v} {k}_{v} \qquad ( 9 )$$

The heat and mass transfer in the thermosyphon will be evaluated through the source terms in the energy and continuity equations. De Schepper et al. [19] have suggested the proper equations for the source terms to simulate condensation and evaporation as given in Table 1. Where Tmix and Tsat are mixture and saturation temperature of the working fluid, respectively. Also, the latent heat (hlv) is the required heat for the evaporation of the liquid at the given saturated temperature.

When simulating nanofluids, two primary approaches are commonly employed. The first approach considers the nanofluid as a single phase, using effective thermophysical properties to represent the bulk nano-fluid. On the other hand, the second approach treats the nanofluid as a two-phase system, comprising the base fluid and a cloud of nanoparticles. The near-molecular mixing between the dilute nanoparticles and the base fluid often justifies adopting a single-phase model for nanofluids as a reasonable assumption in this work.

Since the lower density of the vapor phase cannot effectively retain nanoparticles within itself, it can be assumed that nanoparticles have minimal influence on the thermal properties of the vapor phase. This assumption finds support in numerous prior literature references.

TABLE 1
Mass and Energy Source Terms

| Phase | Temperature | Phase Change | Source term |
|---|---|---|---|
| Liquid | Tₘᵢₓ > Tₛₐₜ | Evaporation | ${S}_{M} = - 0.1 {ρ}_{l} {α}_{l} \frac{{T}_{mix} - {T}_{sat}}{{T}_{sat}}$ |
| | Tₘᵢₓ < Tₛₐₜ | Condensation | ${S}_{M} = 0.1 {ρ}_{v} {α}_{v} \frac{{T}_{sat} - {T}_{mix}}{{T}_{sat}}$ |
| Vapor | Tₘᵢₓ > Tₛₐₜ | Evaporation | ${S}_{M} = 0.1 {ρ}_{l} {α}_{l} \frac{{T}_{mix} - {T}_{sat}}{{T}_{sat}}$ |
| | Tₘᵢₓ < Tₛₐₜ | Condensation | ${S}_{M} = - 0.1 {ρ}_{v} {α}_{v} \frac{{T}_{sat} - {T}_{mix}}{{T}_{sat}}$ |
| Mixture | Tₘᵢₓ > Tₛₐₜ | Evaporation | ${S}_{E} = - 0.1 {ρ}_{l} {α}_{l} \frac{{T}_{mix} - {T}_{sat}}{{T}_{sat}} {h}_{lv}$ |
| | Tₘᵢₓ < Tₛₐₜ | Condensation | ${S}_{E} = 0.1 {ρ}_{v} {α}_{v} \frac{{T}_{sat} - {T}_{mix}}{{T}_{sat}} {h}_{lv}$ |

The effective thermophysical properties of a nanofluid can be derived using mixing theory. The effective density, specific heat transfer, viscosity, and thermal conductivity of the nanofluid can be calculated using the following equations, respectively.

$${ρ}_{nf} = ⌀ρ \text{?} + ( 1 - ⌀ ) {ρ}_{f} \qquad ( 10 )$$

$${C}_{p} \text{?} = ⌀ {C}_{ρ , \text{?}} + ( 1 - ⌀ ) C \text{?} \qquad ( 11 )$$

$${μ}_{nf} = \frac{{μ}_{f}}{{( 1 - ⌀ )}^{2 \text{?}}} \qquad ( 12 )$$

$${k}_{nf} = {k}_{f} \frac{- 2 ⌀ ( {k}_{f} - k \text{?} ) + 2 {k}_{f} + k \text{?}}{⌀ ( {k}_{f} - k \text{?} ) + 2 {k}_{f} + k \text{?}} \qquad ( 13 )$$

$$\text{?} \text{indicates text missing or illegible when filed}$$

Where Ø_represents the nanofluid volume fraction. ρs, Cp,s, and ks denote the density, specific heat, and thermal conductivity of the nanoparticles within the nanofluid, respectively. It is important to highlight that the volume of liquid containing nanoparticles undergoes dynamic changes throughout the boiling process, driven by the volume of fluid (VOF) values calculated for each phase. At each step, the calculated VOF is employed to determine the updated nanofluid volume fraction. Consequently, the physical properties, such as density and thermal conductivity, are dynamically adjusted to accurately represent the evolving composition of the nanofluid as the boiling process evolves. This adaptive approach ensures a more realistic simulation, accounting for the fluid's changing volume fraction during various phases of thermosyphon operation. The properties of the Al2O3 nanoparticles employed in this study are provided in Table 2. The base fluid used in this study is a self-rewetting fluid, and its properties are detailed in Table 3. The characteristics of the self-rewetting nanofluids, including thermal and other relevant properties, can be calculated within the simulation through user-defined functions.

The numerical simulations in this study were performed to investigate the phase change process within a closed, flat-shaped thermosyphon. Given the radial and axial nature of the components involved, without tangential elements, the axisymmetric solution was chosen as the most suitable approach. ANSYS FLUENT 19, with VOF (Volume of Fluid) technique, was employed for conducting these simulations. To simulate the phase change process in Fluent, the source terms, given in Table, 1, have been added to the continuity and energy equations, by employing User Defined Functions (UDFs). Moreover, given the chaotic nature of the boiling process, the two-equation k-ε_model has been adopted in this work, a recommendation endorsed by earlier studies.

The utilization of an axisymmetric model offers a balance between solution accuracy and computational efficiency when compared to both 2D and 3D models. The axisymmetric model provides more accurate results than 2D models while keeping computational costs considerably lower than 3D modeling. Therefore, performing a 2-D axisymmetric analysis on the body of a revolution can help minimize the computational cost needed to solve a 3D problem. Creating an axisymmetric model on a single section plane, positioned on one side of the rotational axis, enables the 2-D axisymmetric analysis on the body of revolution. Using the 2D revolving geometry, the axisymmetric model computes the 3D answer.

TABLE 2
Thermophysical properties of Al2O3 nanoparticles

| | Density | Specific heat | Thermal conductivity |
|---|---|---|---|
| Property | $ρ ( \frac{kg}{{m}^{3}} )$ | ${C}_{p} ( \frac{J}{kg \cdot K} )$ | $k ( \frac{W}{m \cdot K} )$ |
| Al₂O₃ | 3970 | 765 | 40 |

TABLE 3
Working Fluids′ Physical Properties

Working fluid

| | | |
|---|---|---|
| Physical Property | Water [symbol] | Water [symbol] 2% w [symbol] |

| | | |
|---|---|---|
| $Liquid density ( \frac{kg}{{m}^{3}} )$ | [symbol] = 936.0 + [symbol] - [symbol] | [symbol] = 1228 - [symbol] - [symbol] × 10 [symbol] |
| $Vaper density ( \frac{kg}{{m}^{3}} )$ | [symbol] = [symbol] - [symbol] | [symbol] = [symbol] - [symbol] × 10 [symbol] |
| $Latent heat ( \frac{kj}{kg} )$ | 2348.93 | [symbol] |
| $Specific heat of liquid ( \frac{kj}{kg} )$ | [symbol] | [symbol] |
| $Specific heat of vapor ( \frac{kj}{kg} )$ | [symbol] | [symbol] |
| $Thermal conductivity of liquid ( \frac{W}{m E} )$ | [symbol] | [symbol] |

[symbol]

indicates data missing or illegible when filed

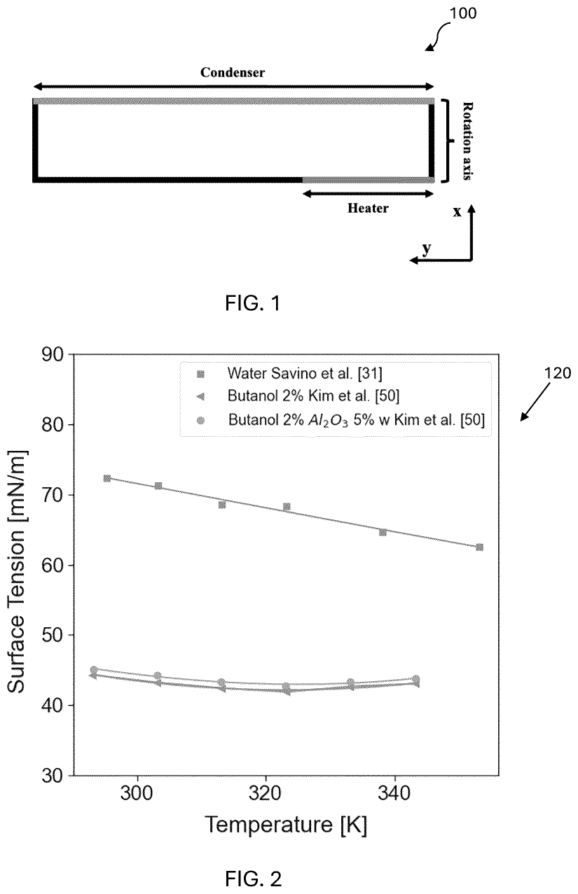

When using the axisymmetric approach in Fluent, the axisymmetric elements should be placed on the XY plane. The rotational axis of symmetry should be aligned with the X-axis, and the revolving body should be in the positive Y coordinate. Consequently, a cylindrical disk-shaped fluid domain can be represented by a rectangle on the X-axis. The used geometry in this work is shown in FIG. 1

FIG. 1 illustrates a schematic diagram of a thermosyphon 100, in accordance with an embodiment. In the embodiment depicted in FIG. 1, the thermosyphon 100 shown can be implemented as a flat-shaped thermosyphon. FIG. 1 thus depicts an axisymmetric domain geometry of a flat-shaped thermosyphon 100. The thermosyphon 100 shown in FIG. 1 has, for example, a thickness of 1 mm, and can be configured from copper. The radius and the height of the thermosyphon 100 in some embodiments may be, for example, 36 mm and 7 mm, respectively.

The inner disk located within the center of the bottom plate, is serving as the heater (evaporator), with a constant heat flux and radius of 12 mm. The same amount of input heat was assumed to be removed from the thermosyphon from the upper disk through the convective boundary condition. The side walls and the rest of the bottom plate are considered to be insulated with zero heat flux. It should be appreciated that the various parameters (e.g., thickness, radius, height, etc.) and materials (e.g., copper, etc.) discussed herein are not limiting features of the embodiments.

As the calculations are based on the secondary phase in the VOF model, liquid, was chosen to be the secondary phase, and the vapor was the primary phase in this simulation. The pressure-velocity coupling was carried out based on the SIMPLE algorithm, and the pressure equations were discretized based on PRESTO! method. The first order upwind and compressive methods were employed for discretizing momentum and energy equations, respectively. To observe the phase change process and the drying out, the simulation was carried out transiently, with a time step of 10-4 s. Also, regarding the convergence criteria, the residual values for the continuity and momentum equations, were 10-4, and 10-6 for energy equation.

In this study, various types of working fluids, including a self-rewetting fluid (aqueous solution of butanol 2%), a self-rewetting nano fluid (aqueous solution of butanol 2% with 5% w Al2O3), and water, were compared to each other, to investigate their effect on the thermosyphon's thermal performance. The self-rewetting fluids show an inverse trend in the interfacial tension after a specific temperature, compared to the ordinary fluids like water. Surface tension is a crucial property influencing the wetting of a fluid on solid surfaces. In the case of self-rewetting fluids, as the temperature increases, their surface tension also increases after a certain point, leading to improved wetting on the heated solid surfaces. This results in the fluid forming a more continuous and uniform film on the heat generating surfaces, enhancing heat transfer efficiency.

This unique property has been observed in aqueous solutions of alcohols like butanol and heptanol, which is attributed to the unique molecular interactions and composition of these solutions. The increase in their interfacial tension, leads to attraction of the liquid to the hotter regions. This specific behavior is beneficial for preventing drying out in the thermosyphon. The physical properties of the working fluids are given in Table 3. The properties of the nanofluid can be derived using Equations 10-13 and data is shown in Tables 2 and 3. The interfacial equations adopted from the studies conducted by Savino et al. for water, and self-rewetting fluids are given below:

$${σ}_{lv , water} = 0.08353 + 2.157 T \times {10}^{- 4} - 1.264 {T}^{2} \times {10}^{- 6} + 1.372 {T}^{3} \times {10}^{- 9}$$

$${σ}_{lv , Bu \text{?} 2 \%} = 0.3455 - 0.002041 T + 3.916 {T}^{2} \times {10}^{- 6} - 1.563 {T}^{3} \times {10}^{- 9}$$

$${σ}_{lv , \text{?}} = - 1.065 + 0.01148 T - 3.92 {T}^{2} \times {10}^{- 5} + 4.421 {T}^{3} \times {10}^{- 8}$$

$$\text{?} \text{indicates text missing or illegible when filed}$$

FIG. 2 illustrates a graph 120 depicting data indicative of surface tensions of different working fluids as functions of temperature in accordance with an embodiment. To illustrate this specific property the interfacial tension relation to temperature for water and the nominated self-rewetting fluids in this study, the change of interfacial tension with temperature has been shown in FIG. 2. The experimental data is represented by dots, providing a real-world basis for our modeling. The continuous lines in the figure represent the equations derived from the interfacial equations, offering a clear comparison between experimental data and modeled predictions. Notably, these equations will be integrated into ANSYS FLUENT as the governing expressions for phases interaction force. Also, the effect of the different filling ratios for the working fluid was studied to optimize the thermal performance of the flat shaped thermosyphon. To initialize the simulation, the desired height of the thermosyphon was patched with liquid for the corresponding filling ratio. The initial temperature of the thermosyphon was set to the working fluid's saturated temperature at the operating pressure which is 0.2 bar. The contact angles of the working fluids on copper also varied. The contact angles for water, butanol 2%, and self-rewetting nanofluid (2% butanol with Al2O3 0.5% w) are 82.5, 80.4, and 75.6°, respectively.

To validate the CFD axisymmetric model, the same geometry and boundary conditions from Zhang et al. have been reproduced. The thermal distribution in the upper plate of the disk-shaped thermosyphon has been compared to the experimental and numerical results reported by Zhang et al. They conducted a 2D axisymmetric model and validated it using an experimental setup for a disk-shaped thermosyphon. The thermosyphon considered in their study can be configured from brass, with an example radius and height of 42.5 mm and 6 mm, respectively. The heat source can be placed at the center of the bottom plate with, for example, a 15 mm radius. The upper plate can serve as a condenser, and the side walls have been insulated.

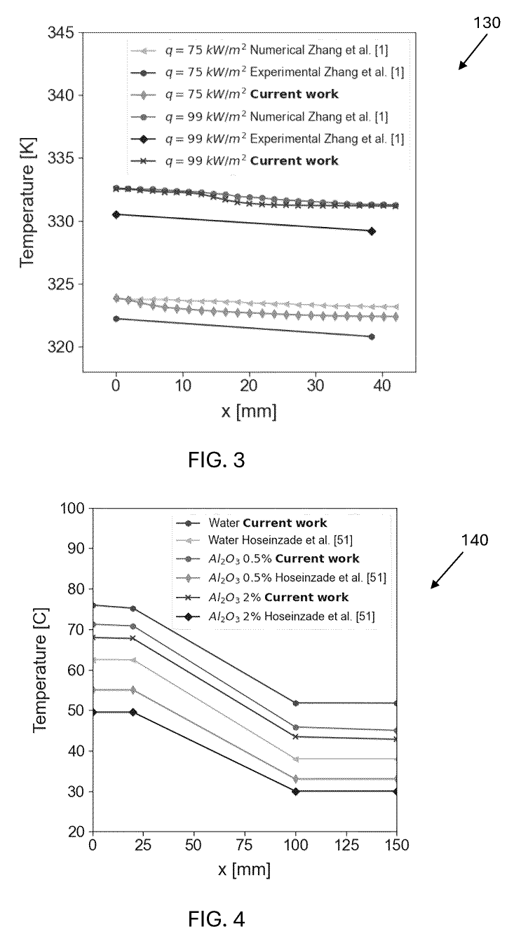

However, it's important to note that their model assumed well-established liquid circulation within the thermosyphon, simplifying the model and excluding considerations for the occurrence of drying out. The working fluid in this comparison is water with a filling ratio of 30%. The temperature distribution is illustrated in FIG. 3 for two different heat loads of Q=75 kW/m2 and Q=99 kW/m2.

FIG. 3 illustrates a graph 130 depicting data indicative of the validation of temperature distribution in a disk shaped thermosyphon, in accordance with an embodiment. It is important to note that the non-perfect adiabatic conditions in the experimental setup may lead to additional heat dissipation from the thermosyphons, resulting in slightly lower temperatures compared to the numerical predictions. This phenomenon is not uncommon in thermosyphon studies and has been acknowledged in the literature. To further support the credibility of our numerical results, we find a commendable agreement between our work and the numerical simulations conducted by Zhang et al. for the same setup.

Furthermore, to examine the model's capability to capture the effect of nanoparticles in the fluid, we conducted a validation study by comparing our simulations with experimental work conducted by Hoseinzadeh et al. In their study, they examined the thermal performance of nanofluids with different concentrations in a two-phase closed thermosyphon. The investigated thermosyphon is a copper tube with a diameter and height of 28 mm and 1500 mm. The lower section of the thermosyphon is injecting heat to the system with a height of 22 mm and the upper 52 mm part of the tube is the condenser. The remaining sections of the walls are insulated. The heat input for this study is set to 100 W, and the comparison involved pure water and Al2O3 nanofluids with concentrations of 0.5% and 2%. The filling ratio for all data points is set at 50%. The results of this example comparison are presented in FIG. 4, which illustrates a graph 140 depicting validation and comparison of temperature distribution in thermosyphon with experimental data with different working fluids (e.g., water and nanofluids), in accordance with an embodiment.

Notably, our numerical results exhibit a slight alternation compared to the experimental results, a phenomenon commonly observed in other literature comparing experimental data with numerical simulations in thermosyphons. This difference is likely attributed to heat losses to the surroundings due to the non-perfect adiabatic conditions in the experimental setup. However, it is worth mentioning that our model accurately captures the nanofluid's effect, and the observed trend aligns with the experimental setup. In both cases, experimentation, and our model, adding the nanoparticles results in lower temperatures in the thermosyphon 100 compared to using pure water.

The grid independency study has been carried out with the different cell numbers for a disk shaped thermosyphon with a radius of 42 mm and height of 7 mm, with a heat input of Q=99 kW/m2. The working fluid was chosen to be water with a filling ratio of 50%. Seven different cell distributions were employed to determine the optimal cell numbers for this study with cell numbers of 4840, 5760, 7200, 8800, 12,720, 20,100, and 28,640 Quad cells. In our study, the formation and departure of vapor bubbles near the heater are critical processes. A sudden alteration in grid size along the gravity direction might introduce errors and lead to simulation divergence. To maintain a smooth transition and prevent numerical instabilities, we implemented a relatively gradual change in mesh size from the boundaries to the domain center while maintaining a fine boundary layer mesh. It is important to note that a higher mesh density has been used for the domain near the top and bottom plates. This is due to the significant role of evaporation and condensation in this area, which requires a more detailed analysis.

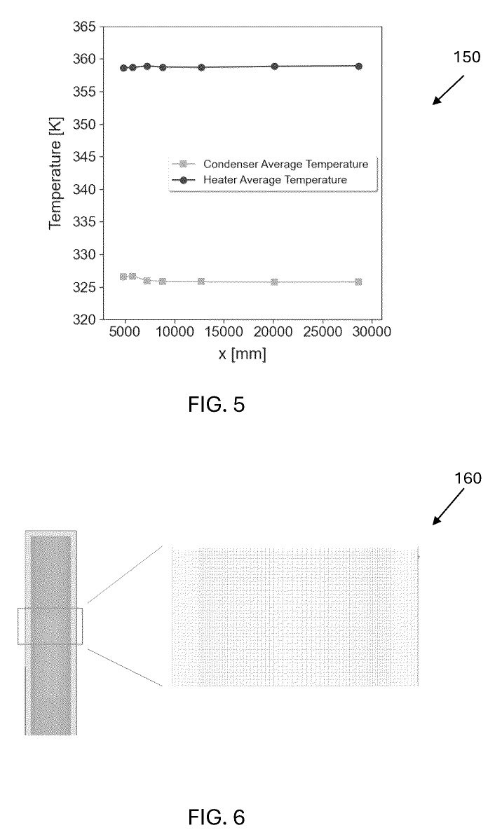

FIG. 5 illustrates a graph 150 of data stemming from a grid independent study for the flat-shaped thermosyphon, in accordance with an embodiment. For each cell distribution, the average temperature of the condenser and evaporator was evaluated, as shown in FIG. 5. The results indicate that a cell number of 12,720 provides accurate results while keeping the computational cost low. Therefore, this cell distribution and element size will be used for the remainder of this study. The mesh distribution in the domain and near walls is demonstrated in FIG. 6 for reference. FIG. 6 illustrates a schematic diagram 160 of grid distribution in the domain and near walls, in accordance with an embodiment.

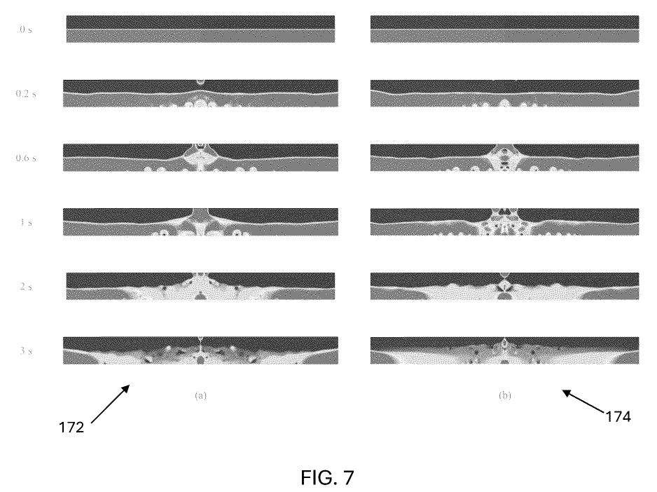

FIG. 7 illustrates the volume fraction of liquid in the boiling process with time steps in graphs 172, (a) water, and graphs 174, (b) SRWF, with 50% filling ratio and 120 W heat input, in accordance with an embodiment. To examine the phase change that occurs within the thermosyphon 100, for example, FIG. 7 displays a contour map of the liquid volume fraction. In this representation, the red color indicates the presence of liquid, while the blue color represents vapor. It's noteworthy that the areas shaded in green represent cells where both liquid and vapor coexist simultaneously. In these green-shaded regions, the density is determined by the volume fraction of both liquid and vapor within each cell. At the initial state (t=0 s), the flat thermosyphon is filled with water and SRWF as the working fluids in cases (a) and (b), with a 50% filling ratio and 120 W heat input. Half of the thermosyphon 100 is colored red, indicating the presence of the liquid phase at the beginning, while the top half is patched with vapor, showing the presence of vapor at the top region.

As time progresses, the heater at the bottom plate transmits heat to the water. Boiling begins specifically at the heater area, with small vapor bubbles forming and rising due to buoyancy. It is worth noting that boiling in water initiates slightly later than in SRWF, due to its slightly higher boiling temperature. Also, there is a consistent increase in the quantity of bubbles, and each individual bubble gradually expands in size. These observations are in accordance with earlier research and contribute to a more profound understanding of the phase change dynamics within the thermosyphon. This progression underscores that boiling is initiated specifically at the heater area, and the chance of dry-out is higher in this region. Furthermore, it is shown in the comparison of cases (a) and (b) that the SRWF exhibits better spreading over the evaporator section.

To investigate the impact of various working fluids in the flat-shaped thermosyphon, this study examined three distinct fluids: pure water, a 2% aqueous solution of butanol, and a nanofluid made from butanol 2% aqueous solution infused with 5% w Al₂O₃ nanoparticles.

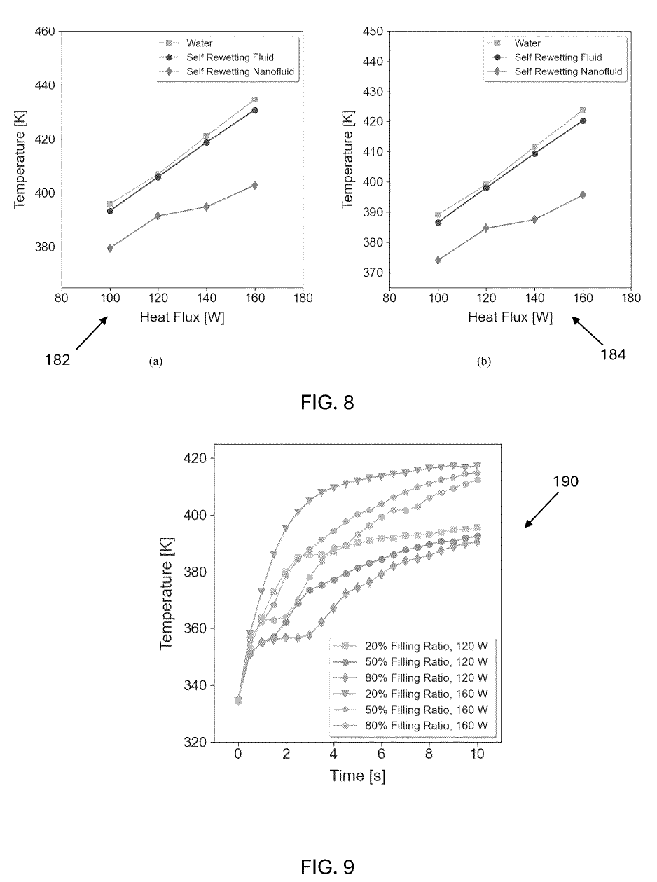

FIG. 8 illustrates a graph 182 of maximum temperature on the heater for different working fluids and heat fluxes, and a graph 184 of average temperature of the heater for different working fluids and heat fluxes, in accordance with an embodiment. FIG. 8 depicts the maximum and average temperature at the bottom plate for different working fluids at various heat inputs. It is crucial to emphasize that all temperatures shown in FIG. 8 are associated with the 20-second time point, indicating the moment when all systems have reached a steady-state condition. Additionally, it is noteworthy that, at each heat input data point, the heat output from the condenser plate precisely matches the heat input. This deliberate alignment ensures the establishment of a steady-state situation for each case. Across all tested heat fluxes, the self-rewetting nanofluid consistently demonstrates superior performance compared to the other working fluids.

Furthermore, even when compared to pure water, the self-rewetting fluid exhibits enhanced performance across all scenarios. It can be observed that the utilization of self-rewetting nanofluid results in a notable decrease in the maximum temperature on the bottom plate. Specifically, at a heat input of 100 W compared to self-rewetting fluid and pure water, the use of self-rewetting nanofluid reduces the maximum bottom plate temperature by approximately 13 K and 16 K, respectively. Notably, this advantage becomes even more pronounced as the heat flux increases. In essence, these findings underscore the substantial benefits of employing self-rewetting nanofluids, particularly in situations involving higher heat fluxes, where their advantages become most evident.

The superior heat transfer performance of self-rewetting nanofluids and self-rewetting fluids can be attributed to several key properties. One significant factor is the contact angle on copper surfaces, measuring at 75.6, 80.4, and 82.5 degrees for self-rewetting nanofluid, self-rewetting fluid, and water, respectively. In contrast to water, both self-rewetting fluids and self-rewetting nanofluids display notably lower contact angles. This property promotes more effective spreading of the liquid on the copper's bottom surface, resulting in the formation of a continuous and thin film. This improved wetting behavior substantially reduces the likelihood of drying out, which can impede heat transfer through localized dry spots.

Another advantage of self-rewetting fluids, compared to water, is their unique surface tension behavior with increasing temperature. Unlike water, self-rewetting fluids demonstrate a reverse trend in sur-face tension as the temperature rises. This unique property of the self-rewetting fluids can cause the liquid to be attracted to hotter surfaces, unlike conventional fluids. The spreading of the liquid over these hotter surfaces mitigates dry out on the hotter regions of the copper evaporator surface. It's crucial to highlight that when working with nanofluids, an interesting phenomenon occurs during boiling. In the boiling process, for example, the presence of nanoparticles within the fluid becomes important. As a portion of the liquid transforms into vapor, the ratio of nanoparticles with higher thermal conductivity than the base fluid increases in the remaining liquid. This elevated concentration of nanoparticles contributes to an augmented thermal conductivity of the nanofluid.

As the vaporization advances nanofluids exhibit enhanced thermal conductivity during this phase transition, further improving their heat transfer capabilities. In summary, the combined effects of improved wetting behavior, surface tension reversal, and the active role of nanoparticles during boiling contribute to the notable benefits observed when employing self-rewetting nanofluids. These properties make them especially advantageous, particularly in situations where efficient and effective heat transfer is essential under higher heat flux conditions. The filling ratio, or the amount of working fluid within a heat transfer system, has a significant impact on its overall thermal performance. In systems like thermosyphons and heat pipes, the filling ratio influences key factors. A lower filling ratio can result in reduced heat capacity because there is less working fluid available to absorb and carry heat. In contrast, a higher filling ratio can enhance the system's ability to efficiently store and distribute the heat.

However, excessive filling ratios can lead to elevated pressure levels and potential operational challenges. Therefore, selecting the optimal filling ratio is essential for achieving the desired heat transfer efficiency while maintaining system stability. For a thorough investigation, we opted for three filling ratios: 0.2, 0.5, and 0.8. This selection enables us to examine various conditions, covering a spectrum from partial to nearly complete filling of the thermosyphon. The choice of these filling ratios is in based on established practices in the field and offers a practical range from 0 to 1 in our study.

FIG. 9 illustrates a graph 19—of data indicative of the average bottom plate temperature over time for different filling ratios and heat power levels using an aqueous solution of butanol 2% as the working fluid, in accordance with an embodiment. In FIG. 9, we have conducted an investigation into the average temperature at the bottom of the system undergoing heat powers of 120 W and 160 W, and we have explored the impact of different filling ratios in a transient study. For this analysis, we have selected an aqueous solution of butanol with a 2% concentration. We have examined filling ratios of 0.2, 0.5, and 0.8 to understand how these variations affect the evaluation of the average temperature at the bottom of the system in 10 s.

It's evident that as time progresses, the temperature of the bottom plate steadily increases. This temperature rise is attributed to the application of higher heat power levels, with the 160 W case exhibiting a more rapid temperature increase compared to the 120 W case. However, it's important to note that there are slight fluctuations in temperature over time, which can be observed as minor deviations from the overall temperature increase trend. Furthermore, the filling ratio of the thermosyphon plays a notable role in temperature increase of the bottom plate. Systems with higher filling ratios, such as 0.8, tend to exhibit lower temperatures on the bottom plate, and the rate of temperature increase in these cases is comparatively slower. In contrast, systems with lower filling ratios, such as 0.2, experience higher temperatures and a more rapid temperature increase.

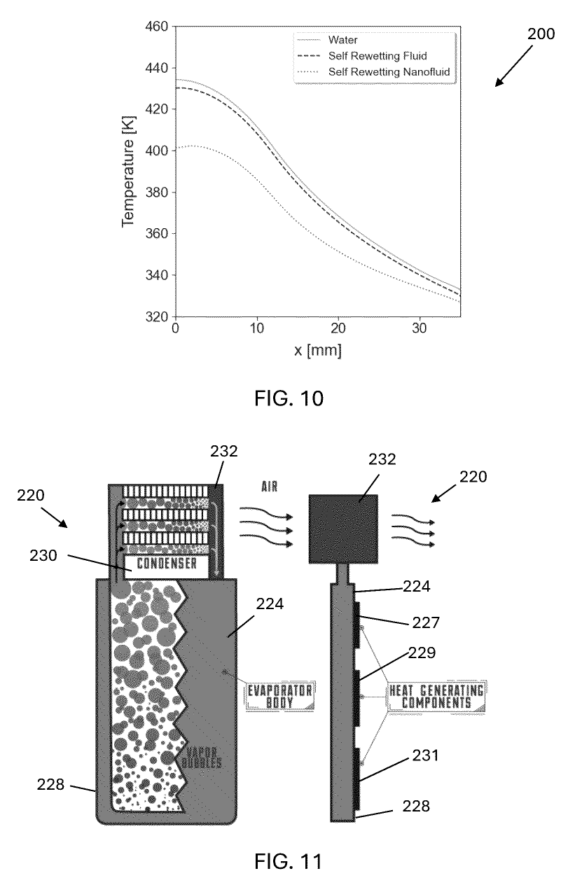

FIG. 10 illustrates a graph 200 of data indicative temperature distribution on the bottom plate for different working fluids with 160 W heat input and 50% filling ratio, in accordance with an embodiment. In FIG. 10, the temperature distribution on the bottom plate is presented for various working fluids: water, self-rewetting fluid (2% aqueous butanol solution), and self-rewetting nanofluid (2% aqueous butanol solution with 5% w Al2O3 nanoparticles). The heat input and filling ratio for this investigation are 160 W and 50%, respectively.

It can be seen that while self-rewetting fluid maintains lower temperatures across the entire bottom plate compared to water, self-rewetting nano-fluid notably outperformed both working fluids in terms of thermal performance. Also, the center of the bottom plate exhibits the highest temperature. It's noteworthy that the observation of the center of the bottom plate exhibiting the highest temperature aligns with the configuration of our system. Placing the heat source at the center of the bottom plate concentrates the heat flux in this region, emphasizing the critical aspect of our study. The primary focus of our work is to address and mitigate potential dry-out concerns, particularly in this central part of the system.

The described study has dived into the transient dynamics of heat transfer and phase change within a flat-shaped thermosyphon, exploring various parameters and working fluids. The investigation includes the impact of different working fluids, filling ratios, and heat power on the thermal performance of the system. Results have shown that outperform traditional working fluids, demonstrating enhanced heat transfer capabilities and a reduced risk of dry-out. The unique characteristic of self-rewetting fluids and self-rewetting nanofluids is their reversed trend of surface tension with temperature rise, which attracts the liquid to hot regions, effectively preventing dry-out.

Additionally, the enhancing thermal conductivity of nanofluids with the boiling process further contributes to their superior performance, allowing for more efficient heat transfer processes. Another important factor impacting the thermal performance of each working fluid is its contact angle when being in contact with copper. The contact angle is lowest for the self-rewetting nanofluid. This reduced contact angle promotes the liquid spreading on the evaporator surface and hinders the occurrence of dry outs.

Furthermore, the filling ratio effect on temperature profiles and heat transfer rates has been studied, indicating that higher filling ratios lead to lower temperatures on the bottom plate. Also, higher filling ratios have been associated with slower temperature increases on the bottom plate, a phenomenon that has important implications for transient system design and performance optimization. This comprehensive study provides valuable insights into the optimization of thermosyphon systems for various applications, including thermal management in electronic cooling systems. Future research can build upon these findings to further enhance the efficiency and reliability of thermosyphon-based heat transfer systems.

FIG. 11 illustrates an example of a system 220 for cooling electronic components, in accordance with an embodiment. In FIG. 11, a front view of the system 220 is shown at the left side of the drawing, while a side view of the same system 220 is depicted at the right side of the figure. The system 220 includes a thermosyphon 232 that includes a condenser 230 with respect to an evaporator 228 that includes an evaporator body 224. The thermosyphon 232 can be implemented as a flat-shaped thermosyphon such as discussed previously. In the particular confirmation shown in FIG. 11, the thermosyphon 232 can move a large amount of heat compared to a similar-sized heat pipe or thermosyphon because in this particular configuration, there is no counterflow (liquid and vapor moving in opposing directions). This “loop” aspect makes this possible by designing a discrete vapor line to the heat sink, condensing within the heatsink, and liquid returning down a separate fluid line. It should be appreciated that the particular configuration shown in FIG. 11 is not a limiting feature of the embodiments but can be implemented to include the use of the flat-shaped thermosyphon disclosed herein. The system 220 can therefore be used to cool one or more electronic components such as the heat generating components 227, 229, 231.

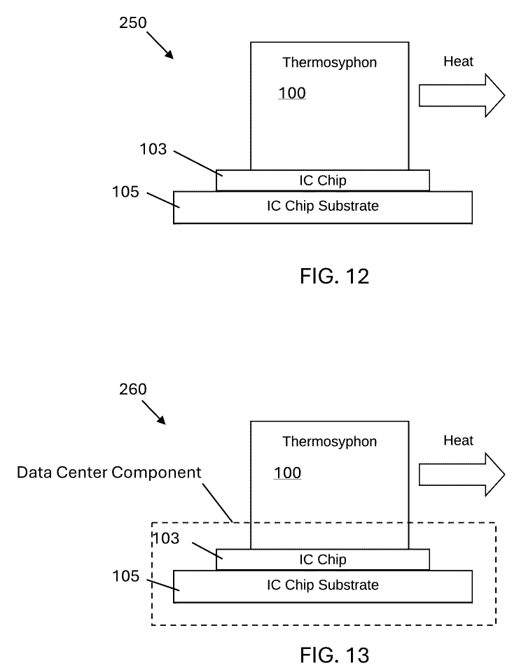

FIG. 12 illustrates an exemplary embodiment of an apparatus for cooling an electronic component using a thermosyphon 100, in accordance with the present disclosure. As shown, an electronic component 110 is positioned external to the thermosyphon 100 and is thermally coupled thereto such that the electronic component 110 and the thermosyphon 100 are in thermal communication with one another. In various embodiments, the thermal coupling may be achieved by direct contact, a thermally conductive interface material, a heat spreader, a thermal pad, or another suitable heat transfer structure. The electronic component 110 is not disposed within the thermosyphon 100, thereby facilitating practical implementation in electronic systems.

The thermosyphon 100 comprises a substantially flat-shaped enclosure defining an internal cavity containing a working fluid 120. The thermosyphon 100 includes an evaporator section 116 disposed adjacent to a base plate 118, a condenser section 124 positioned opposite the evaporator section 116, and at least one internal return path 126 configured to return condensed liquid to the evaporator section 116.

During operation, heat generated by the electronic component 110 is transferred across the thermal coupling to the evaporator section 116 of the thermosyphon 100. The transferred heat causes the working fluid 120 at the evaporator section 116 to undergo a phase change from liquid to vapor. The vapor then flows within the thermosyphon 100, as indicated by vapor flow arrows 128, toward the condenser section 124.

The condenser section 124 is thermally coupled to one or more heat dissipation structures 130, such as fins or extended surfaces, which facilitate heat rejection to the surrounding environment. As heat is dissipated, the vapor condenses back into a liquid phase at the condenser section 124. The condensed liquid returns to the evaporator section 116 via the return path 126, thereby completing a continuous thermosyphon circulation cycle.

In the illustrated embodiment, the working fluid 120 comprises a self-rewetting fluid or a self-rewetting nanofluid. The self-rewetting working fluid exhibits a surface tension characteristic that increases with increasing temperature over at least a portion of an operating temperature range. As a result, liquid within the thermosyphon 100 is preferentially drawn toward higher-temperature regions of the evaporator section 116, thereby improving wetting of the heat transfer surface and reducing the risk of dry-out during operation.

FIG. 13 illustrates a detailed view of the evaporator region of the thermosyphon 100, emphasizing the behavior of the self-rewetting nanofluid during heat transfer. In this embodiment, the working fluid 120 comprises a self-rewetting base fluid with nanoparticles 134 dispersed therein. The nanoparticles 134 may include metal oxide nanoparticles, such as aluminum oxide (Al₂O₃), although other nanoparticle materials and compositions may be employed.

As the working fluid 120 undergoes boiling at the evaporator section 116, a portion of the liquid phase transitions into vapor, resulting in a localized increase in nanoparticle concentration in the remaining liquid. This increased concentration enhances the effective thermal conductivity of the working fluid 120, thereby further improving heat transfer performance during phase change.

Additionally, due to the self-rewetting properties of the working fluid 120, liquid is actively attracted toward higher-temperature regions of the evaporator section 116. This behavior promotes formation of a substantially continuous liquid film on the heat transfer surface, mitigates localized dry-out conditions, and enables stable thermal performance under elevated heat flux conditions.

The combined effects of surface-tension-driven liquid redistribution and nanoparticle-enhanced thermal conductivity allow the thermosyphon 100 to efficiently dissipate heat from the externally positioned electronic component 110, making the disclosed apparatus particularly well suited for cooling high-power electronic devices.

The embodiments disclosed herein address the growing challenges associated with thermal management of high-power, miniaturized electronic devices by providing a thermosyphon-based cooling apparatus that efficiently removes heat through two-phase heat transfer while maintaining a compact and manufacturable structure. By employing a flat-shaped thermosyphon thermally coupled to an external electronic component, the disclosed system effectively dissipates heat generated at high power densities without relying on complex active cooling mechanisms. The use of phase-change heat transfer enables substantial heat removal at relatively low temperature gradients, thereby reducing operating temperatures, minimizing thermal and mechanical stresses, and improving device reliability and longevity.

Moreover, the incorporation of self-rewetting fluids and self-rewetting nanofluids within the thermosyphon directly mitigates the dry-out phenomenon that has historically limited thermosyphon performance under high heat flux conditions. The unique surface-tension behavior of self-rewetting fluids promotes liquid transport toward hotter regions of the evaporator, while dispersed nanoparticles enhance thermal conductivity during boiling. Together, these features enable stable, efficient, and scalable cooling performance across a wide range of operating conditions. As a result, the disclosed embodiments provide an effective and practical solution to the limitations of conventional single-phase cooling and traditional thermosyphon designs, making them well suited for modern electronic and integrated circuit applications requiring robust thermal management.

In addition, the disclosed thermosyphon-based cooling apparatus, methods and systems, are particularly advantageous for data center environments, where high server densities, continuous operation, and increasing rack-level power consumption place stringent demands on thermal management systems. The passive, gravity-assisted operation of the thermosyphon enables efficient heat removal without requiring pumps or complex control hardware, thereby reducing energy consumption, system complexity, and maintenance requirements.

Note that in some embodiments, the disclosed thermosyphon such as thermosyphon 100, for example, may be comprise a two-phase closed thermosyphon (TPCT) or wickless heat pipe. In two-phase closed thermosyphons, fluid fluid circulation is governed by the gravity force instead of the capillary force in the wicked section. The input heat from the evaporator section, located at the bottom of the TPCT, turns the existing liquid into vapor. The vapor goes up and reaches the condenser section in the upper part of the TPCT. The vapor condenses and the obtained liquid falls back to the evaporator section because of the gravity force. Thermosyphons' functionality, their low-cost fabrication, and the low conductivity of wicked parts in conventional heat pipes can make TPCTs as an important and relevant cooling setup priority. Considering their high efficiency, cost effectiveness, simple structure, and reliability, TPCTs have been widely used in various applications ranging from waste heat recovery to electronic cooling systems. Flat two-phase thermosyphon heat spreaders can be placed between electronic devices and heat sinks to yield a more uniform temperature distribution at high heat fluxes.

Based on the foregoing, it can be appreciated that a number of different embodiments are disclosed. For example, in an embodiment, an apparatus for cooling electronic components, can include at least one thermosyphon thermally coupled to at least one electronic component, wherein the at least one thermosyphon is configured to transfer heat away from the electronic component by phase change of a working fluid circulating within the at least one thermosyphon.

In an embodiment, the at least one thermosyphon can be implemented as a flat-shaped thermosyphon having an evaporator region, a condenser region, and a fluid return path formed within a flattened enclosure.

In an embodiment, the electronic component can be, for example, a data center electronic device, an integrated circuit, a processor, a power electronic module, or a printed circuit board assembly.

In an embodiment, the working fluid can be a self-rewetting fluid.

In an embodiment, the self-rewetting fluid exhibits a surface tension that increases with increasing temperature over at least a portion of an operating temperature range, thereby promoting liquid migration toward heated regions of the thermosyphon.

In an embodiment, the self-rewetting fluid can be an aqueous solution containing an alcohol.

In an embodiment, the working fluid further can be a self-rewetting nanofluid including nanoparticles dispersed within the self-rewetting fluid.

In an embodiment, the nanoparticles can comprise metal oxide nanoparticles.

In an embodiment, the self-rewetting fluid can be configured to reduce dry-out at an evaporator surface by attracting liquid toward regions of higher temperature.

In an embodiment, the at least one thermosyphon has a working fluid filling ratio selected to reduce a maximum temperature at an evaporator plate during steady-state operation.

In an embodiment, the flat-shaped thermosyphon can be configured to be mounted directly to a heat-generating surface of the electronic component.

An embodiment can further include a plurality of thermosyphons arranged in parallel to cool multiple electronic components or multiple regions of a single electronic component, the plurality of thermosyphon including the at least one thermosyphon.

In an embodiment, the self-rewetting nanofluid can be configured to maintain stable thermal performance under high heat flux conditions relative to a thermosyphon using water as a working fluid.

In an embodiment, an evaporator surface of the thermosyphon can comprise a metallic heat transfer surface.

In an embodiment, a method for cooling an electronic component, can further involve: thermally coupling a thermosyphon to a heat-generating surface of the electronic component; circulating a working fluid within the thermosyphon by evaporation at an evaporator region and condensation at a condenser region; and using a self-rewetting working fluid within the thermosyphon such that, as temperature increases at the evaporator region, surface tension of the working fluid increases and draws liquid toward hotter regions, thereby reducing dry-out and enhancing heat transfer during operation of the electronic component.

In an embodiment, a system for cooling electronic components, can include an electronic component; and at least one thermosyphon thermally coupled to the electronic component, wherein the thermosyphon contains a self-rewetting working fluid configured to circulate within the thermosyphon by phase change and to preferentially wet higher-temperature regions of an evaporator surface during operation.

In an embodiment, the thermosyphon can be a flat-shaped thermosyphon configured for direct attachment to the electronic component, and the self-rewetting working fluid can be a self-rewetting nanofluid including nanoparticles dispersed within an aqueous alcohol solution, the nanoparticles increasing thermal conductivity of the working fluid during boiling.

The ability of the self-rewetting working fluid and self-rewetting nanofluid to prevent evaporator dry-out under sustained high heat flux conditions allows the cooling system to maintain stable performance during peak computational loads. Furthermore, the flat-shaped geometry and external thermal coupling configuration facilitate integration with existing server architectures, cold plates, or heat spreaders, making the disclosed solution well suited for scalable deployment in modern data centers seeking to improve thermal efficiency, reliability, and overall energy effectiveness.

It will be appreciated that variations of the above-disclosed and other features and functions, or alternatives thereof, may be desirably combined into many other different systems or applications. It will also be appreciated that various presently unforeseen or unanticipated alternatives, modifications, variations or improvements therein may be subsequently made by those skilled in the art which are also intended to be encompassed by the following claims.

What is claimed is:

1. An apparatus for cooling electronic components, comprising:
at least one thermosyphon thermally coupled to at least one electronic component, wherein the at least one thermosyphon is configured to transfer heat away from the electronic component by phase change of a working fluid circulating within the at least one thermosyphon.

2. The apparatus of claim 1, wherein:
the at least one thermosyphon comprises a flat-shaped thermosyphon having an evaporator region, a condenser region, and a fluid return path formed within a flattened enclosure; or
the at least one thermosyphon comprises a two-phase closed thermosyphon or wickless heat pipe.

3. The apparatus of claim 1, wherein the electronic component comprises at least one of a data center electronic device, an integrated circuit, a processor, a power electronic module, or a printed circuit board assembly.

4. The apparatus of claim 1, wherein the working fluid comprises a self-rewetting fluid.

5. The apparatus of claim 4, wherein the self-rewetting fluid exhibits a surface tension that increases with increasing temperature over at least a portion of an operating temperature range, thereby promoting liquid migration toward heated regions of the thermosyphon.

6. The apparatus of claim 4, wherein the self-rewetting fluid comprises an aqueous solution containing an alcohol.

7. The apparatus of claim 6, wherein the alcohol comprises butanol.

8. The apparatus of claim 7, wherein the aqueous solution contains about 0.5% to about 5% alcohol by weight.

9. The apparatus of claim 1, wherein the working fluid further comprises a self-rewetting nanofluid including nanoparticles dispersed within the self-rewetting fluid.

10. The apparatus of claim 9, wherein the nanoparticles comprise metal oxide nanoparticles.

11. The apparatus of claim 10, wherein the metal oxide nanoparticles comprise aluminum oxide (Al₂O₃).

12. The apparatus of claim 4, wherein the self-rewetting fluid is configured to reduce dry-out at an evaporator surface by attracting liquid toward regions of higher temperature.

13. The apparatus of claim 1, wherein the at least one thermosyphon has a working fluid filling ratio selected to reduce a maximum temperature at an evaporator plate during steady-state operation.

14. The apparatus of claim 2, wherein the flat-shaped thermosyphon is configured to be mounted directly to a heat-generating surface of the electronic component.

15. The apparatus of claim 1, further comprising a plurality of thermosyphons arranged in parallel to cool multiple electronic components or multiple regions of a single electronic component, the plurality of thermosyphon including the at least one thermosyphon.

16. The apparatus of claim 9, wherein the self-rewetting nanofluid is configured to maintain stable thermal performance under high heat flux conditions relative to a thermosyphon using water as a working fluid.

17. The apparatus of claim 1, wherein an evaporator surface of the thermosyphon comprises a metallic heat transfer surface.

18. A method for cooling an electronic component, comprising:
thermally coupling a thermosyphon to a heat-generating surface of the electronic component;
circulating a working fluid within the thermosyphon by evaporation at an evaporator region and condensation at a condenser region; and
using a self-rewetting working fluid within the thermosyphon such that, as temperature increases at the evaporator region, surface tension of the working fluid increases and draws liquid toward hotter regions, thereby reducing dry-out and enhancing heat transfer during operation of the electronic component.

19. A system for cooling electronic components, comprising:
an electronic component; and
at least one thermosyphon thermally coupled to the electronic component, wherein the thermosyphon contains a self-rewetting working fluid configured to circulate within the thermosyphon by phase change and to preferentially wet higher-temperature regions of an evaporator surface during operation.

20. The system of claim 19, wherein:
the thermosyphon comprises a flat-shaped thermosyphon configured for direct attachment to the electronic component; and
the self-rewetting working fluid comprises a self-rewetting nanofluid including nanoparticles dispersed within an aqueous alcohol solution, the nanoparticles increasing thermal conductivity of the working fluid during boiling.
